(19) United States
(12) Patent Application Publication
(10) Pub. No.: US 2026/0142586 A1
(43) Pub. Date: May 21, 2026

(54) POWER CONVERSION APPARATUS WITH OPTIMIZED COMPONENT ARRANGEMENT STRUCTURE BASED ON HEAT GENERATION FOR HIGH-EFFICIENCY COOLING

(71) Applicant: KOREA ELECTRONICS TECHNOLOGY INSTITUTE, Seongnam-si (KR)

(72) Inventors: Sang Min PARK, Bucheon-si (KR); Jun Hyuk CHOI, Bucheon-si (KR); Jin Hong KIM, Suwon-si (KR); Joon Sung PARK, Seoul (KR); Byong Jo HYON, Anyang-si (KR); Yongsu NOH, Seoul (KR); Dongmyoung JOO, Seoul (KR); Daeyeon HWANG, Incheon (KR); Poo Reum JANG, Incheon (KR); Hyoung-Kyu YANG, Seoul (KR); Seok Won KIM, Seoul (KR)

(21) Appl. No.: 19/396,750

(22) Filed: Nov. 21, 2025

(30) Foreign Application Priority Data
Nov. 21, 2024 (KR) 10-2024-0166952

(51) Int. Cl. H02M 7/00; H05K 7/20

(52) U.S. Cl. CPC H02M 7/003; H05K 7/209

(57) ABSTRACT

Proposed is a power conversion apparatus with an optimized component arrangement structure based on heat generation for high-efficiency cooling. The apparatus may include a heat sink, a first heat generator provided on a first surface of the heat sink, and a second heat generator electrically connected to the first heat generator and provided on a second opposing surface of the heat sink. The apparatus may also include a third heat generator electrically connected to the first and second heat generators and provided on the second surface of the heat sink. The first heat generator may be configured to generate more heat than each of the second and third heat generators. The heat sink may include a cooling channel configured to flow coolant therethrough to cool the first to third heat generators. The power conversion apparatus can rapidly cool heat emitted from a plurality of heat generation units.

### CROSS-REFERENCE TO RELATED APPLICATIONS

This application claims priority under 35 U.S.C. § 119 to Korean Patent Application No. 10-2024-0166952, filed on Nov. 21, 2024, in the Korean Intellectual Property Office, the disclosure of which is incorporated herein by reference in its entirety.

### BACKGROUND

### Technical Field

The following disclosure relates to a power conversion apparatus with an optimized component arrangement structure based on heat generation for high-efficiency cooling, and more particularly, to a power conversion apparatus with an optimized component arrangement structure based on heat generation for high-efficiency cooling capable of rapidly cooling heat emitted from a plurality of heat generation units.

### Description of Related Technology

Power conversion apparatuses include a power module including power semiconductor devices, an inductor module connected to the power module, and a capacitor module.

### SUMMARY

One aspect is a power conversion apparatus with an optimized component arrangement structure based on heat generation for high-efficiency cooling capable of cooling a plurality of heat generation components with a single heat sink to reduce a size and weight of the device, and at the same time, prevents heat from a heat generation unit with the largest heat generation from spreading to other devices, thereby enhancing the stability and reliability of the device.

Another aspect is a power conversion apparatus that includes: a heat sink; a first heat generation unit provided on one surface of the heat sink; a second heat generation unit electrically connected to the first heat generation unit and provided on the other surface of the heat sink; and a third heat generation unit electrically connected to the first and second heat generation units and provided on the other surface of the heat sink, in which the heat generation of the first heat generation unit is greater than that of the second and third heat generation units, and the heat sink has a cooling channel through which coolant flows to cool the first to third heat generation units.

The first heat generation unit may include an inductor module that includes: at least one inductor; an inductor case accommodating the at least one inductor; and a mold fixing the inductor to the inductor case, and the mold may have a thermal connectivity greater than or equal to a predetermined reference value.

### BRIEF DESCRIPTION OF THE DRAWINGS

FIG. 1 is a perspective view of a power conversion apparatus according to an embodiment of the present disclosure.

FIG. 2 is a cross-sectional view of the power conversion apparatus according to an embodiment of the present disclosure.

FIG. 3 is a plan perspective view of the power conversion apparatus according to an embodiment of the present disclosure.

FIG. 4 is a bottom perspective view of the power conversion apparatus according to an embodiment of the present disclosure.

FIG. 5 is a perspective view of the power conversion apparatus according to another embodiment of the present disclosure.

FIG. 6 is a cross-sectional view of the power conversion apparatus according to another embodiment of the present disclosure.

FIG. 7 is a perspective view of an embodiment of an inductor module.

FIG. 8 is a perspective view of an embodiment of a capacitor module.

### DETAILED DESCRIPTION

A power conversion apparatus positions a power module and an inductor module on the same plane and mounting them on the same PCB substrate for connection; or alternatively the power module and the inductor module may be arranged adjacent to each other and electrically connected via a bus bar. However, among the components within a power conversion apparatus, the inductor module typically generates the largest amount of heat. As in the conventional power conversion apparatuses, when the power module and the inductor module are arranged adjacent to each other, the heat generated by the inductor module may affect devices vulnerable to heat, such as the power module.

In this case, devices vulnerable to heat may be damaged to increase the likelihood of failure in the power conversion apparatus. As a result, there may be the problem in that the significant reduction in the stability and reliability of the power conversion apparatus.

Furthermore, to simultaneously cool the plurality of heat generation units with a single heat sink, the heat sink should have a high heat dissipation capacity, requiring it to be large. In this case, the power conversion apparatus becomes larger in size, and the weight of the power conversion apparatus also increases, resulting in a significant decrease in space utilization.

The above-described objects, features, and advantages of the present disclosure will become more obvious from the following detailed description provided in relation to the accompanying drawings. The following specific structural or functional descriptions are only exemplified for the purpose of explaining the embodiments according to the concept of the present disclosure, and the embodiments according to the concept of the present disclosure may be implemented in various forms and should not be construed as limited to the embodiments described herein or in the application. Since embodiments according to the concept of the present disclosure may be variously modified and may have several forms, specific embodiments will be illustrated in the accompanying drawings and will be described in detail in the present specification or application. However, it is to be understood that the present disclosure is not limited to specific embodiments, but includes all modifications, equivalents, and substitutions falling in the spirit and the scope of the present disclosure. Terms such as ‘first’, ‘second’, or the like, may be used to describe various components, but these components are not to be construed as being limited to these terms. The terms are used only to distinguish one component from another component. For example, a first component may be named a second component and the second component may also be named the first component, without departing from the scope of the present disclosure. It is to be understood that when one component is referred to as being connected to or coupled to another component, it may be connected directly to or coupled directly to another component or be connected to or coupled to another component with the other component interposed therebetween. On the other hand, it is to be understood that when one component is referred to as being connected directly to or coupled directly to another component, it may be connected to or coupled to another component without the other component interposed therebetween. Other expressions for describing the relationship between components, such as between and immediately between or adjacent to and directly adjacent to, etc., should be interpreted similarly. Terms used in the present specification are used only in order to describe specific embodiments rather than limiting the present disclosure. Singular expressions are intended to include plural expressions unless the context clearly represents otherwise. It is to be understood that terms “include,” “have,” or the like, used in the present specification specify the presence of features, numerals, steps, operations, components, parts, or a combination thereof described in the present specification, but do not preclude the presence or addition of one or more other features, numerals, steps, operations, components, parts, or a combination thereof. Unless indicated otherwise, it is to be understood that all the terms used in the specification including technical and scientific terms have the same meaning as those that are generally understood by those who skilled in the art. Terms generally used and defined in a dictionary are to be interpreted as the same meanings with meanings within the context of the related art, and are not to be interpreted as ideal or excessively formal meanings unless clearly indicated in the present specification. Hereinafter, embodiments of the present disclosure will be described in detail with reference to the accompanying drawings. Throughout the accompanying drawings, the same reference numerals indicate the same members.

Hereinafter, a preferred embodiment of a power conversion apparatus with an optimized component arrangement structure based on heat generation for high-efficiency cooling 1 according to the present disclosure will be described in detail with reference to the attached drawings.

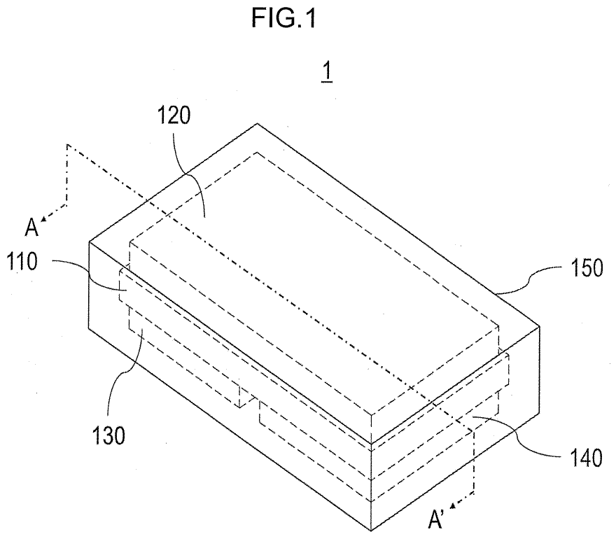

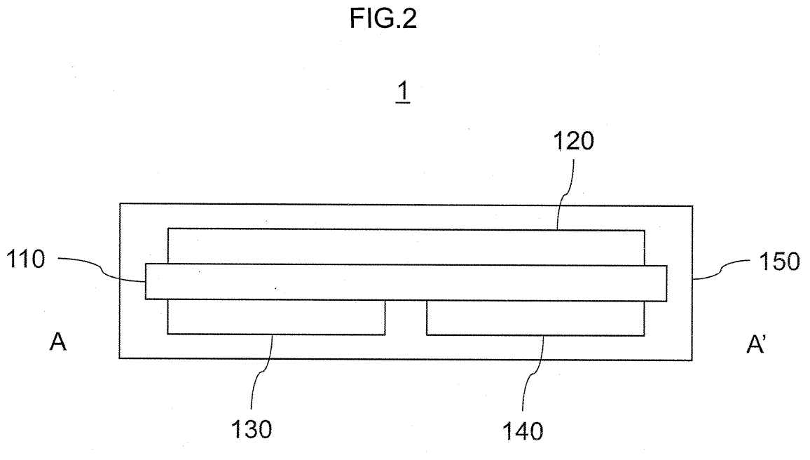

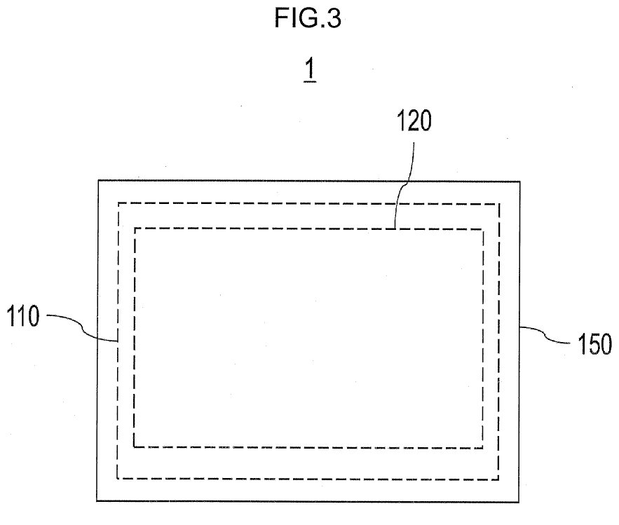

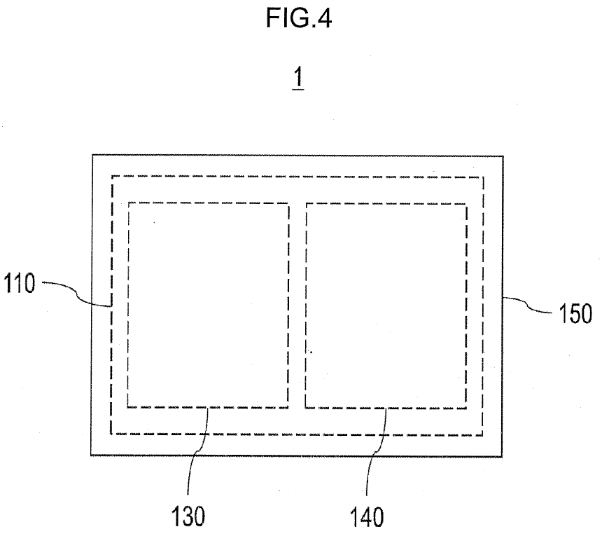

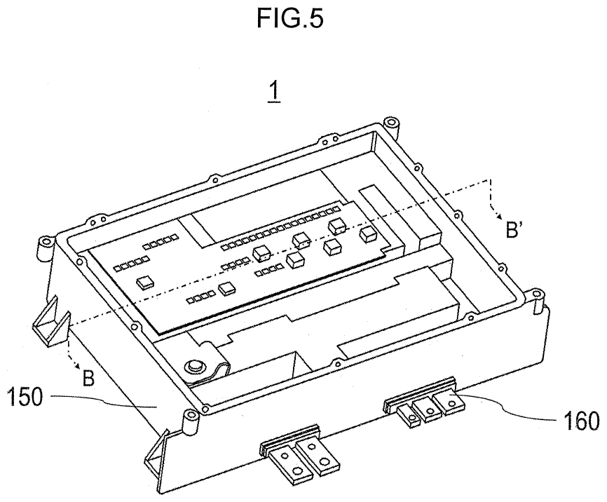

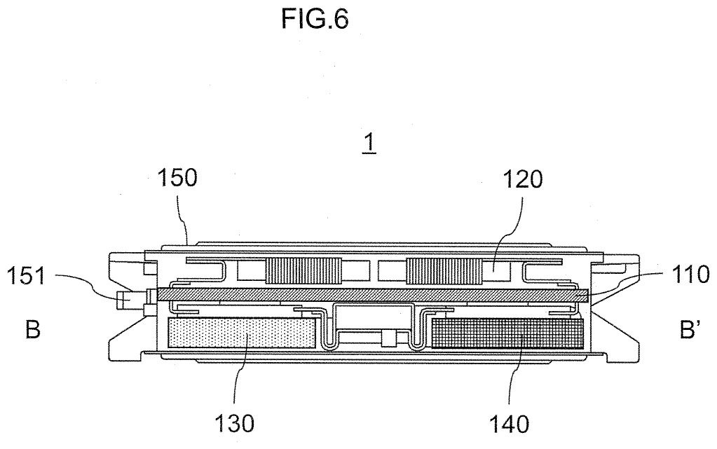

FIG. 1 is a perspective view of a power conversion apparatus 1 according to an embodiment of the present disclosure, FIG. 2 is a cross-sectional view of the power conversion apparatus 1 according to an embodiment of the present disclosure, FIG. 3 is a plan perspective view of the power conversion apparatus 1 according to an embodiment of the present disclosure, FIG. 4 is a bottom perspective view of the power conversion apparatus 1 according to an embodiment of the present disclosure, FIG. 5 is a perspective view of the power conversion apparatus 1 according to another embodiment of the present disclosure, and FIG. 6 is a cross-sectional view of the power conversion apparatus 1 according to another embodiment of the present disclosure. Specifically, FIG. 2 is a cross-sectional view taken along line A-A′ of FIG. 1. And FIG. 6 is a cross-sectional view taken along line B-B′ of FIG. 5.

The power conversion apparatus 1 according to an embodiment of the present disclosure includes a heat sink 110, a first heat generation unit 120, a second heat generation unit 130, a third heat generation unit 140, an outer case 150, and a power transmission/reception terminal 160.

The heat sink 110 releases heat generated from the first to third heat generation units 120, 130, and 140 to the outside of the outer case 150. To this end, the heat sink 110 includes a cooling channel for water-cooling the first to third heat generation units 120, 130, and 140. Specifically, the heat of the first to third heat generation units 120, 130, and 140 adjacent to both surfaces of the heat sink 110 is released to the outer case 150 via coolant, thereby reducing the temperature of the first to third heat generation units 120, 130, and 140.

The heat sink 110 includes at least one material selected from among copper and aluminum. Specifically, the heat sink 110 may be manufactured by including at least one material selected from among copper and aluminum, which are materials with high thermal conductivity, to release heat transferred through the cooling channel to the outside. This allows the first to third heat generation units 120, 130, and 140 arranged on both surfaces of the heat sink 110 to be effectively cooled by utilizing water cooling, which has a greater cooling effect than air cooling.

Next, the first to third heat generation units 120, 130, and 140 will be described.

The first heat generation unit 120 is provided on one surface of the heat sink 110. Specifically, the first heat generation unit 120 is provided in close contact with one surface of the heat sink 110. Here, the heat generation of the first heat generation unit 120 is greater than that of the second and third heat generation units 130 and 140. Therefore, among the devices included in the power conversion apparatus 1, a device with a large heat generation capacity may be arranged on the first heat generation unit 120 so as to be separated from the second and third heat generation units 130 and 140 by the heat sink 110.

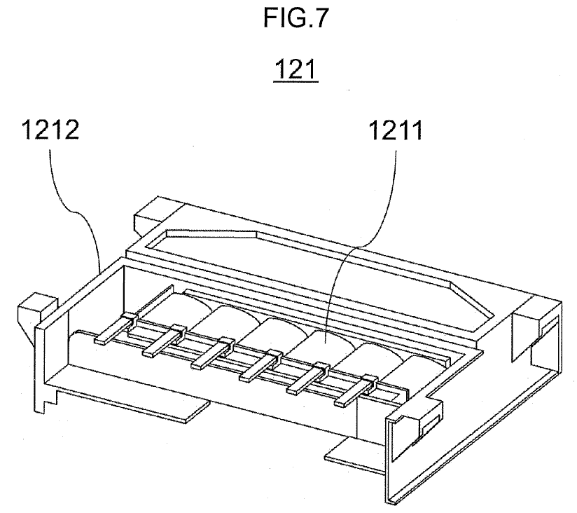

FIG. 7 is a perspective view of an embodiment of the inductor module.

The first heat generation unit 120 includes an inductor module 121. The inductor module 121 includes at least one inductor 1211, an inductor case 1212, and a mold. For the typical power conversion apparatus, the inductor 1211 generates the largest amount of heat. The inductor module 121 may be installed in the first heat generation unit 120 to prevent the heat from spreading to other devices.

The inductor 1211 is a passive component and is connected to other modules within the power conversion apparatus 1 of the present disclosure. For example, the inductor 1211 may be connected to the power module of the second heat generation unit 130 or the capacitor module 141 of the third heat generation unit 140.

The inductor case 1212 accommodates at least one inductor 1211. Specifically, a PCB substrate is fixedly accommodated within the inductor case 1212, and at least one inductor 1211 is mounted on the PCB substrate.

The mold may fix the inductor 1211 to the inductor case 1212. Here, the mold has a thermal connectivity greater than or equal to a predetermined reference value. Specifically, since the mold is filled within the inductor case 1212 using a silicon potting technique, the inductor 1211 fixed to the PCB substrate may be fixed to the inductor case 1212. In addition, in order to eliminate the heat generation of the inductor 1211, the mold having the thermal connectivity greater than or equal to the predetermined reference value may be used to effectively transfer the heat generation of the inductor 1211 to the heat sink 110.

That is, by including the inductor module 121 with the largest heat generation among the power conversion apparatus 1 in the first heat generation unit 120, the cooling effect of the inductor module 121 may increase.

The second heat generation unit 130 is electrically connected to the first heat generation unit 120 and is provided on the other surface of the heat sink 110. Specifically, the second heat generation unit 130 is electrically connected to the first heat generation unit 120 and may supply current to the inductor module provided in the first heat generation unit 120. In addition, the second heat generation unit 130 is provided in close contact with the other surface of the heat sink 110 and may transfer the heat generated from the second heat generation unit 130 to the heat sink 110.

The second heat generation unit 130 includes a power module. The power module includes at least one power semiconductor device. Specifically, the power semiconductor device included in the power module may be a device manufactured using either silicon (Si) or silicon carbide (SiC) materials.

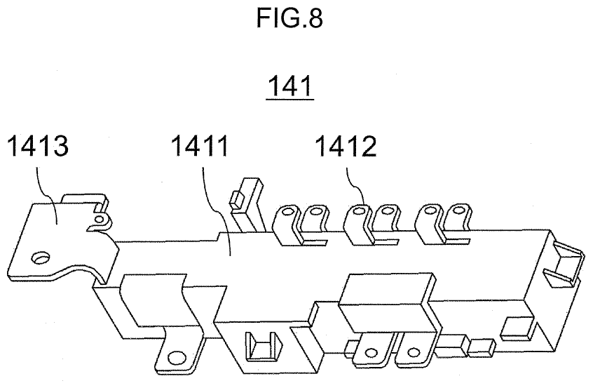

FIG. 8 is a perspective view of an embodiment of a capacitor module.

The third heat generation unit 140 is electrically connected to the first and second heat generation units 120 and 130 and is provided on the other surface of the heat sink 110. Specifically, the third heat generation unit 140 is electrically connected to the first and second heat generation units 120 and 130, and the third heat generation unit 140 may be a capacitor module 141.

The capacitor module 141 serves to filter the DC voltage input or output through a power transmission/reception terminal 160 of the power conversion apparatus 1 of the present disclosure. Specifically, the capacitor module 141 includes at least one capacitor, a capacitor case 1411 that accommodates at least one capacitor therein, a capacitor terminal 1412 provided in the capacitor case 1411 to connect the capacitor to an external module, and a case fixing part 1413 that fixes the capacitor case 1411 to the outer case 150. For example, at least one capacitor may be a film capacitor having a cylindrical structure or a film capacitor having a rectangular structure, but is not limited to the description herein.

Through this, the capacitor module 141 may be stably accommodated in the inner case 150, and the capacitor may be stably electrically connected to the inductor module 121 and the power module 131 provided in the first and second heat generation units 120 and 130.

That is, by providing the power module and capacitor module 141 with relatively smaller heat generation than the inductor module 121 in the second and third heat generation units 130 and 140, respectively, there is an effect of structurally blocking the influence of the heat generation of the first heat generation unit 120.

The outer case 150 houses a heat sink 110 and the first to third heat generation units 120, 130, and 140 therein. Specifically, the outer case 150 houses the heat sink 110 and the first to third heat generation units 120, 130, and 140 therein to protect the power conversion apparatus 1 from the outside, and when the heat sink 110 is provided with the cooling channel, the outer case 150 may be provided with the cooling channel port 151 for allowing the coolant circulating in the cooling channel to circulate inside and outside of the outer case 150.

The power transmission/reception terminal 160 is connected to the first to third heat generation units 120, 130, and 140 and transmits power to the inside and outside. Referring to FIG. 5, at least one power transmission/reception terminal 160 protruding from one surface of the outer case 150 may be provided. Through this, the power conversion apparatus 1 and other devices may be connected, and the power may be transmitted to or provided to other devices.

According to the power conversion apparatus with optimized component arrangement structure based on heat generation for high-efficiency cooling described above, the first heat generation unit with the largest heat generation, is arranged on one surface of the heat sink, while the second and third heat generation units, which generate relatively less heat, are arranged on the other surface of the heat sink, thereby effectively cooling the first heat generation unit.

Furthermore, by arranging the heat sink between the first heat generation unit and the second and third heat generation units, the heat from the first heat generation unit is prevented from spreading to the second and third heat generation units, thereby protecting the second and third heat generation units from the heat generation from the first heat generation unit.

Furthermore, since the single heat sink may cool the plurality of heat generation units, it may be miniaturized, resulting in a smaller power conversion apparatus and a significantly reduced weight.

The present disclosure should not be construed to being limited to the above-mentioned embodiment. The present disclosure may be applied to various fields and may be variously modified by those skilled in the art without departing from the scope of the present disclosure claimed in the claims. Therefore, it is obvious to those skilled in the art that these alterations and modifications fall within the scope of the present disclosure.

What is claimed is:

1. A power conversion apparatus, comprising:
a heat sink;
a first heat generator provided on a first surface of the heat sink;
a second heat generator electrically connected to the first heat generator and provided on a second opposing surface of the heat sink; and
a third heat generator electrically connected to the first and second heat generators and provided on the second surface of the heat sink,
wherein the first heat generator is configured to generate more heat than each of the second and third heat generators, and
wherein the heat sink comprises a cooling channel configured to flow coolant therethrough to cool the first to third heat generators.

2. The power conversion apparatus of claim 1, wherein the first heat generator includes an inductor module that includes:
at least one inductor;
an inductor case accommodating the at least one inductor; and
a mold fixing the inductor to the inductor case, and
wherein the mold has a thermal connectivity greater than or equal to a predetermined reference value.
